(19) United States
(12) Patent Application Publication
(10) Pub. No.: US 2024/0032301 A1
(43) Pub. Date: Jan. 25, 2024

(54) NOR-TYPE MEMORY DEVICE, METHOD OF MANUFACTURING NOR-TYPE MEMORY DEVICE, AND ELECTRONIC APPARATUS INCLUDING MEMORY DEVICE

(71) Applicant: INSTITUTE OF MICROELECTRONICS, CHINESE ACADEMY OF SCIENCES, Beijing (CN)

(72) Inventor: Huilong Zhu, Poughkeepsie, NY (US)

(21) Appl. No.: 18/043,324

(22) PCT Filed: Feb. 22, 2022
(86) PCT No.: PCT/CN2022/077257

§ 371 Date: Feb. 27, 2023

(30) Foreign Application Priority Data
Mar. 8, 2021 (CN) 202110252927.4

(51) Int. Cl. H10B 51/20; H10B 43/10; H10B 51/10; H10B 43/27

(52) U.S. Cl. CPC H10B 51/20; H10B 43/10; H10B 51/10; H10B 43/27

(57) ABSTRACT

Disclosed are a NOR-type memory device, a method of manufacturing the NOR-type memory device, and an electronic apparatus including the NOR-type memory device. According to an embodiment, the NOR-type memory device may include: a plurality of device layers disposed on a substrate, wherein each of the plurality of device layers includes a stack of a first source/drain layer, a first channel layer, and a second source/drain layer; and a gate stack that extends vertically with respect to the substrate to pass through the stack in the each of the plurality of device layers, wherein the gate stack includes a gate conductor layer and a memory functional layer disposed between the gate conductor layer and the stack, and a memory cell is defined at an intersection of the gate stack and the stack.

### CROSS REFERENCE TO RELATED APPLICATION(S)

This application is a National Stage Application of International Application No. PCT/CN2022/077257, filed Feb. 22, 2022, entitled “NOR-type memory device, method of manufacturing NOR-type memory device, and electronic apparatus including memory device” which claims priority to Chinese Patent Application No. 202110252927.4, filed on Mar. 8, 2021 and entitled, the entire content of which is incorporated herein in its entirety by reference.

### TECHNICAL FIELD

The present disclosure relates to the field of semiconductors, and more particularly, to a NOR-type memory device, a method of manufacturing the NOR-type memory device, and an electronic apparatus including the memory device.

### BACKGROUND

In a planar device such as a Metal Oxide Semiconductor Field Effect Transistor (MOSFET), a source, a gate and a drain are arranged in a direction substantially parallel to a substrate surface. Due to such an arrangement, the planar device is difficult to be further scaled down. In contrast, in a vertical device, a source, a gate and a drain are arranged in a direction substantially perpendicular to a substrate surface. As a result, the vertical device is easier to be scaled down compared to the planar device.

Vertical devices may be stacked to increase the integration density. However, this may lead to poor performance. Because in order to stack a plurality of devices conveniently, polycrystalline silicon is usually used as a channel material, resulting in a greater resistance compared with using monocrystalline silicon as the channel material. In addition, it is also desired to adjust a doping level in a source/drain region and a channel independently.

### SUMMARY

In view of the above, the present disclosure aims to provide, among others, a NOR-type memory device with an improved performance, a method of manufacturing the NOR-type memory device, and an electronic apparatus including the memory device.

According to an aspect of the present disclosure, there is provided a vertical memory device, including: a plurality of device layers disposed on a substrate, wherein each of the plurality of device layers includes a stack of a first source/drain layer, a first channel layer, and a second source/drain layer; and a gate stack that extends vertically with respect to the substrate to pass through the stack in the each of the plurality of device layers, wherein the gate stack includes a gate conductor layer and a memory functional layer disposed between the gate conductor layer and the stack, and a memory cell is defined at an intersection of the gate stack and the stack.

According to another aspect of the present disclosure, there is provided a method of manufacturing a vertical memory device, including: disposing a plurality of device layers on a substrate, wherein each of the plurality of device layers includes a stack of a first source/drain layer, a first channel layer, and a second source/drain layer; forming a processing channel that extends vertically with respect to the substrate to pass through the stack in the each of the plurality of device layers; and forming a gate stack in the processing channel, wherein the gate stack includes a gate conductor layer and a memory functional layer disposed between the gate conductor layer and the stack, and a memory cell is defined at an intersection of the gate stack and the stack.

According to another aspect of the present disclosure, there is provided an electronic apparatus including the NOR-type memory device described above.

According to embodiments of the present disclosure, a stack of single crystal material may be used as a building block to build a three-dimensional (3D) NOR-type memory device. Therefore, when a plurality of memory cells are stacked, an increase of resistance may be suppressed. In addition, each layer may be doped separately, so that a doping level in a source/drain region and a doping level in a channel region may be adjusted separately.

### BRIEF DESCRIPTION OF THE DRAWINGS

The above and other objects, features, and advantages of the present disclosure will become more apparent from following descriptions on embodiments thereof with reference to attached drawings, in which:

FIGS. 1 to 11(c) are schematic diagrams showing some stages in a process of manufacturing a NOR-type memory device according to an embodiment of the present disclosure;

FIGS. 12(a) and 12(b) are schematic diagrams showing some stages in a process of manufacturing a NOR-type memory device according to another embodiment of the present disclosure;

FIG. 13 is a schematic diagram showing some stages in a process of manufacturing a NOR-type memory device according to another embodiment of the present disclosure;

FIGS. 14 and 15 are schematic diagrams showing some stages in a process of manufacturing a NOR-type memory device according to another embodiment of the present disclosure;

FIGS. 16(a) to 17(b) are schematic diagrams showing some stages in a process of manufacturing a NOR-type memory device according to an embodiment of the present disclosure;

FIG. 18 schematically shows an equivalent circuit diagram of a NOR-type memory device according to an embodiment of the present disclosure,

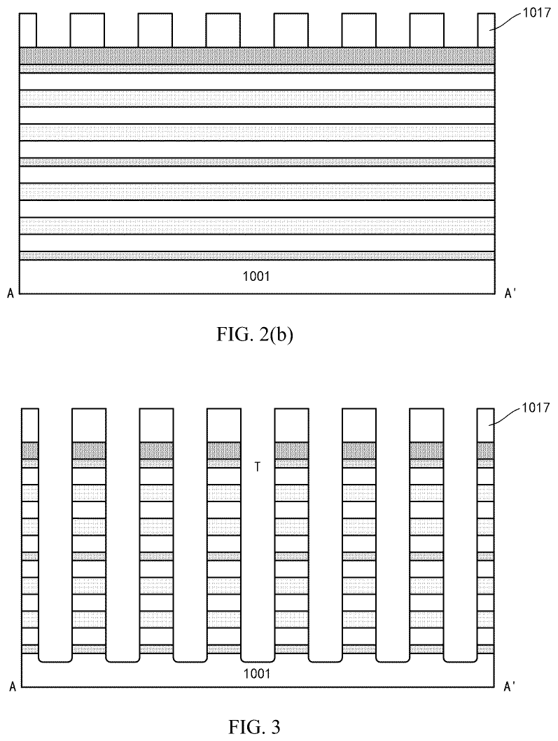

wherein FIGS. 2(a), 7(a), 11(a) and 12(a) are top views, and FIG. 2(a) shows positions of line AA′ and line BB′;

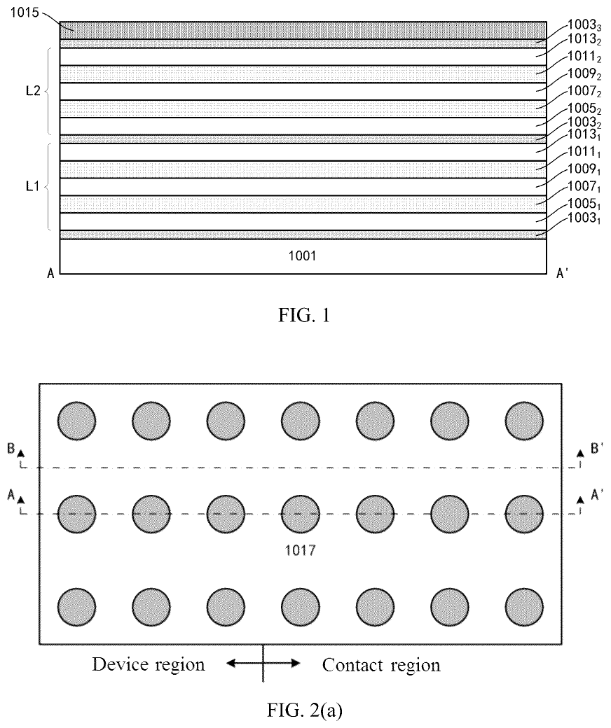

FIGS. 1, 2(b), 3 to 6, 7(b), 8(a), 9(a), 10(a), 11(b), 12(b), 16(a), and 17(a) are cross-sectional views taken along line AA′;

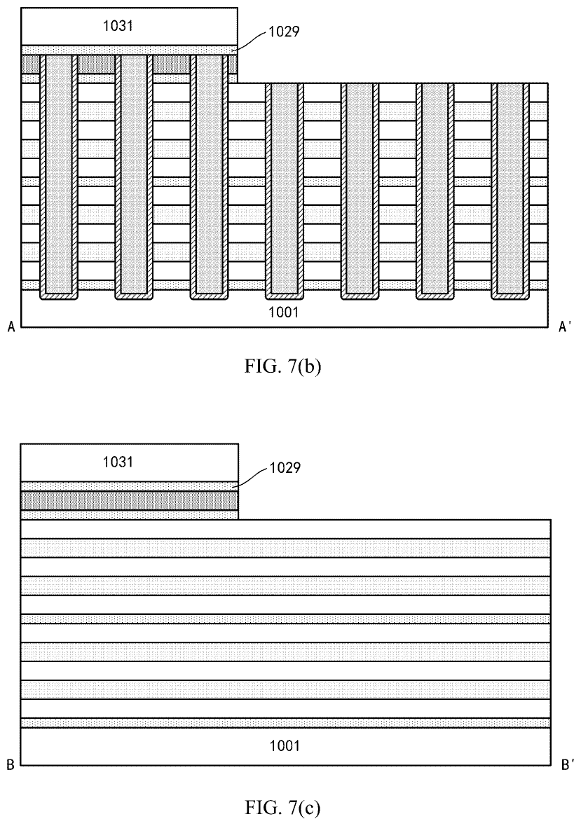

FIGS. 7(c), 8(b), 9(b), 10(b), 11(c), 13 to 15, 16(b), and 17(b) are cross-sectional views taken along line BB′.

Throughout the drawings, the same or similar reference numbers denote the same or similar elements.

### DETAILED DESCRIPTION OF EMBODIMENTS

Hereinafter, descriptions are given with reference to embodiments shown in the attached drawings. However, it is to be understood that these descriptions are illustrative and not intended to limit the present disclosure. Further, in the following, known structures and technologies are not described to avoid obscuring the present disclosure unnecessarily.

In the drawings, various structures according to the embodiments are schematically shown. However, they are not drawn to scale, and some features may be enlarged while some features may be omitted for sake of clarity. Moreover, shapes and relative sizes and positions of regions and layers shown in the drawings are also illustrative, and deviations may occur due to manufacture tolerances and technique limitations in practice. Those skilled in the art may also devise regions/layers of other different shapes, sizes, and relative positions as desired in practice.

In the context of the present disclosure, when a layer/element is recited as being “on” a further layer/element, the layer/element may be disposed directly on the further layer/element, or otherwise there may be an intervening layer/element interposed therebetween. Further, if a layer/element is “on” a further layer/element in an orientation, then the layer/element may be “under” the further layer/element when the orientation is turned.

A memory device according to an embodiment of the present disclosure is based on a vertical device. The vertical device may include an active region arranged on a substrate in a vertical direction (a direction substantially perpendicular to a surface of the substrate). The active region includes source/drain regions at upper and lower ends of the active region and a channel region between the source/drain regions. A conductive channel may be formed between the source/drain regions through the channel region. In the active region, the source/drain regions and the channel region may be defined by, for example, a doping concentration.

According to an embodiment of the present disclosure, the active region may be defined by a stack of a first source/drain layer, a first channel layer, and a second source/drain layer on the substrate. The source/drain regions may be formed in the first source/drain layer and the second source/drain layer respectively, and the channel region may be formed in the first channel layer. A gate stack may extend through the stack, so that the active region may surround a periphery of the gate stack. Here, the gate stack may include a memory functional layer, such as at least one of a charge trapping material or a ferroelectric material, so as to achieve a memory function. In this way, the gate stack is cooperated with an active region opposite to the gate stack, so as to define a memory cell. Here, the memory cell may be a flash memory cell.

A plurality of gate stacks may be arranged to pass through the stack, so as to define a plurality of memory cells at intersections of the plurality of gate stacks and the stack. In a plane where the stack is located, these memory cells are arranged into an array (for example, generally, a two-dimensional array arranged in rows and columns) corresponding to the plurality of gate stacks.

Since the vertical device is easy to be stacked, the memory device according to an embodiment of the present disclosure may be a three-dimensional (3D) array. Specifically, a plurality of such stacks may be arranged in the vertical direction. The gate stack may extend vertically to pass through the plurality of stacks. In this way, for a single gate stack, it intersects the plurality of stacks stacked in the vertical direction to define a plurality of memory cells stacked in the vertical direction.

In a NOR (NOT OR)-type memory device, each memory cell may be connected to a common source line. In view of such configuration, every two adjacent memory cells in the vertical direction may share the same source line connection, so as to save wirings. For example, the above-mentioned stack may further include a second channel layer and a third source/drain layer. In this way, the first source/drain layer, the first channel layer, and the second source/drain layer may be cooperated with the gate stack as described above, so as to define a first memory cell. In addition, the second source/drain layer, the second channel layer, and the third source/drain layer may be cooperated with the gate stack likewise, so as to define a second memory cell. The first memory cell and the second memory cell are stacked on each other and share the same second source/drain layer. The second source/drain layer may be electrically connected to the source line.

The above-mentioned stack may be formed by epitaxial growth on the substrate and may be a single crystal semiconductor material. Compared with a conventional process of forming a plurality of gate stacks stacked on each other and then forming a vertical active region which passes through these gate stacks, it is easier to form an active region (especially the channel layer) of single crystal in the present disclosure. In addition, various layers in the stack may be doped in situ respectively during the growth, and there may be a doping concentration interface between different doped layers. In this way, a doping distribution in the vertical direction may be better controlled. The stack of the first source/drain layer, the channel layer, and the second source/drain layer may form a bulk material, and thus the channel region is formed in the bulk material. In this case, the process is relatively simple.

Such vertical memory device may be manufactured as follows. Specifically, a plurality of device layers may be disposed on the substrate. Each of the plurality of device layers includes the stack of the first source/drain layer, the first channel layer, and the second source/drain layer (and optionally, the second channel layer and the third source/drain layer as described above). For example, these layers may be provided by epitaxial growth. A thickness of each layer, especially a thickness of the channel layer, may be controlled during epitaxial growth. In addition, in situ doping may be performed during epitaxial growth, so as to achieve a desired doping polarity and doping concentration. Here, each layer in the stack may include the same material. In this case, the so-called “layers” may be defined by a doping concentration interface between them.

A sacrificial layer may be formed between at least one pair of adjacent device layers or even each pair of adjacent device layers. Such sacrificial layer may then be replaced by an isolation layer, so as to electrically isolate an adjacent bit line. The sacrificial layer may have etching selectivity with respect to the device layer.

A processing channel, which extends vertically with respect to the substrate to pass through the stack in the each of the plurality of device layers, may be formed. In the processing channel, a sidewall of the sacrificial layer may be exposed, so that the sacrificial layer may be replaced by the isolation layer. A gate stack may be formed in the processing channel.

The present disclosure may be presented in various forms, and some examples of which will be described below. In the following description, the selection of various materials is involved. In selecting the materials, etching selectivity is considered in addition to the function of the material (for example, a semiconductor material is used to form the active region, a dielectric material is used to form an electrical isolation, and a conductive material is used to form an electrode, an interconnection structure, etc.). In the following description, the required etching selectivity may or may not be indicated. It should be clear to those skilled in the art that when etching a certain material layer is mentioned below, if it is not mentioned that other layers are also etched or the drawing does not show that other layers are also etched, then this etching may be selective, and the material layer may have etching selectivity with respect to other layers exposed to the same etching recipe.

FIGS. 1 to 11(c) are schematic diagrams showing some stages in a process of manufacturing a NOR-type memory device according to an embodiment of the present disclosure.

As shown in FIG. 1, a substrate 1001 is provided. The substrate 1001 may be a substrate in any form, for example, but not limited to, a bulk semiconductor material substrate such as a bulk silicon (Si) substrate, a Semiconductor On Insulator (SOI) substrate, a compound semiconductor substrate such as an SiGe substrate, or the like. Hereinafter, the bulk Si substrate, such as a Si wafer, will be described by way of example for the convenience of description.

On the substrate 1001, a memory device, such as a NOR-type flash memory, may be formed as described below. A memory cell in the memory device may be an n-type device or a p-type device. Here, an n-type memory cell is described as an example. For this purpose, a p-type well may be formed in the substrate 1001. Therefore, the following description, in particular the description of a doping type, is for forming the n-type device. However, the present disclosure is not limited thereto.

On the substrate 1001, a sacrificial layer 1003₁ used to define the isolation layer, a first source/drain layer 1005₁ used to define the source/drain region, a first channel layer 1007₁ used to define the channel region, a second source/drain layer 1009₁ used to define the source/drain region, a second channel layer 1011₁ used to define the channel region, and a third source/drain layer 1013₁ used to define the source/drain region may be formed by, for example, epitaxial growth. The first source/drain layer 1005₁, the first channel layer 1007₁, the second source/drain layer 1009₁, the second channel layer 1011₁, and the third source/drain layer 1013₁ will then define an active region of the device, and may be referred to as “device layer” which is dented by L1 in FIG. 1.

Each layer grown on the substrate 1001 may be a single crystal semiconductor layer. These layers may have a crystal interface or a doping concentration interface between each other because they are grown or doped separately.

The sacrificial layer 1003₁ may then be replaced by an isolation layer used to isolate the device from the substrate. A thickness of the sacrificial layer 1003₁ may correspond to a thickness of the isolation layer that is desired to be formed, for example, about 10 nm to 50 nm. According to a circuit design, the sacrificial layer 1003₁ may be omitted. Each of the first source/drain layer 1005₁, the second source/drain layer 1009₁, and the third source/drain layer 1013₁ may form a source/drain region by doping (for example, in situ doping during growth), and may have a thickness of about 20 nm to 50 nm, for example. Each of the first channel layer 1007₁ and the second channel layer 1011₁ may define a gate length, and may have a thickness corresponding to a gate length that is desired to be formed, for example, about 15 nm to 100 nm.

These semiconductor layers may include various suitable semiconductor materials, for example, an element semiconductor material such as Si or Ge, a compound semiconductor material such as SiGe, etc. Considering the following process of replacing the sacrificial layer 1003₁ by the isolation layer, the sacrificial layer 1003₁ may have etching selectivity with respect to the device layer. For example, the sacrificial layer 1003₁ may include SiGe (an atomic percentage of Ge, for example, is about 15% to 30%), and the device layer may include Si. In this example, both the source/drain layer and the channel layer in the device layer include Si, but the present disclosure is not limited thereto. For example, it is also possible for adjacent layers in the device layer to have etching selectivity with respect to each other.

The first source/drain layer 1005₁, the second source/drain layer 1009₁, and the third source/drain layer 1013₁ may be doped in situ when growing, so as to form the source/drain regions subsequently. For example, for the n-type device, an n-type doping may be performed, and a doping concentration may be, for example, about 1E19 cm⁻³ to 1E21 cm⁻³. In addition, the first channel layer 1007₁ and the second channel layer 1011₁ may not be intentionally doped, or may be lightly doped by in situ doping during growth, so as to improve a short channel effect, adjust a threshold voltage (Vₜ) of the device, and the like. For example, for the n-type device, a p-type doping may be performed, and a doping concentration is about 1E17 cm⁻³ to 1E19 cm⁻³.

In order to increase an integration density, a plurality of device layers may be provided. For example, a device layer L2 may be provided on the device layer L1 by epitaxial growth. The device layer L1 is separated from the device layer L2 by a sacrificial layer 1003₂ used to define the isolation layer. Although only two device layers are shown in FIG. 1, the present disclosure is not limited thereto. According to the circuit design, it is possible to omit the isolation layer between certain device layers. Similarly, the device layer L2 may have a first source/drain layer 1005₂, a first channel layer 1007₂, a second source/drain layer 1009₂, a second channel layer 1011₂, and a third source/drain layer 1013₂. Respective layers in each device layer L1 and L2 may have the same or similar thickness and/or material, or may have different thicknesses and/or materials. Here, for convenience of description only, it is assumed that each device layer L1 and L2 has the same configuration.

On such layers formed on the substrate 1001, a hard mask layer 1015 may be provided to facilitate patterning. For example, the hard mask layer 1015 may include nitride (for example, silicon nitride). A thickness of the hard mask layer 1015 is about 50 nm to 200 nm.

It is also possible to provide a sacrificial layer 1003₃, which is used to define the isolation layer, between the hard mask layer 1015 and the device layer L2. For sacrificial layers 1003₂ and 1003₃, reference may be made to the above description of the sacrificial layer 1003₁.

In the following, on the one hand, a processing channel which may reach the sacrificial layer is desired, so as to replace the sacrificial layer by the isolation layer. On the other hand, it is desired to define a region used to form a gate. According to an embodiment of the present disclosure, the two aspects may be implemented in combination. Specifically, a gate region may be defined by the processing channel.

For example, as shown in FIGS. 2(a) and 2(b), a photoresist 1017 may be formed on the hard mask layer 1015. The photoresist 1017 may be patterned to have a plurality of openings by photolithography, and these openings may define positions of the processing channels. The opening may have various suitable shapes, such as round, rectangular, square, polygon, etc. and have a suitable size, such as a diameter or side length of about 20 nm to 500 nm. Here, these openings (especially in the device region) may be arranged in an array form, such as a two-dimensional array along horizontal and vertical directions in paper in FIG. 2(a). The array may then define an array of memory cells. Although the openings are shown to be formed on the substrate (including the device region where the memory cell will be fabricated subsequently and the contact region where a contact portion will be fabricated subsequently) with a basically consistent size and a substantially uniform density in FIG. 2(a), the present disclosure is not limited thereto. The size and/or density of the openings may be changed. For example, a density of the openings in the contact region may be less than a density of the openings in the device region, so as to reduce the resistance in the contact region.

As shown in FIG. 3, the patterned photoresist 1017 may be used as an etching mask to etch each layer on the substrate 1001 by anisotropic etching, such as reactive ion etching (RIE), so as to form a processing channel T. RIE may be performed in a substantially vertical direction (for example, a direction perpendicular to the substrate surface) and may be performed into the substrate 1001. Accordingly, a plurality of vertical processing channels T are left on the substrate 1001. A processing channel T in the device region also defines the gate region. Then, the photoresist 1017 may be removed.

Currently, the sidewall of the sacrificial layer is exposed in the processing channel T. Accordingly, the sacrificial layer may be replaced by the isolation layer via the exposed sidewall. Considering a function of supporting the device layers L1 and L2 during replacement, a support layer may be formed.

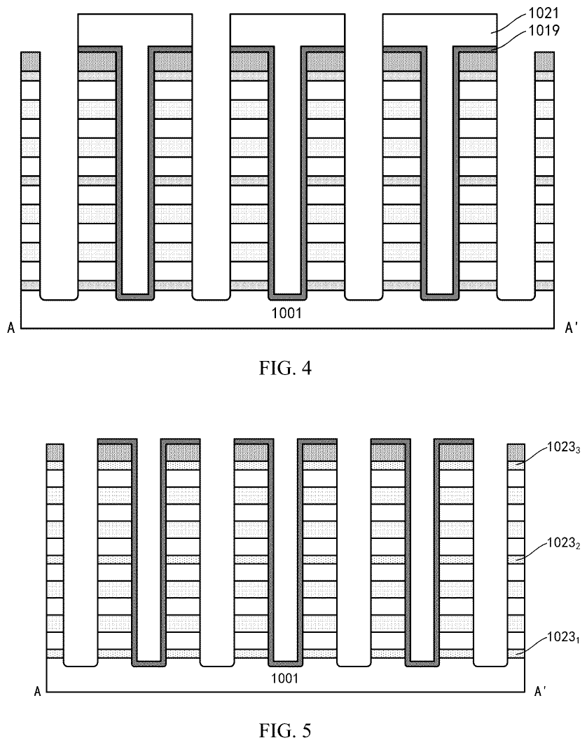

For example, as shown in FIG. 4, a support material layer may be formed on the substrate 1001 by, for example, deposition, such as chemical vapor deposition (CVD). The support material layer may be formed in a substantially conformal manner. Considering the etching selectivity, especially the etching selectivity with respect to the hard mask layer 1015 (nitride in this example) and the subsequently formed isolation layer (oxide in this example), the support material layer may include, for example, SiC. By forming a photoresist 1021 and performing selective etching such as RIE with the photoresist 1021 for example, a part of the support material layer in one or more of processing channels T may be removed while a part of the support material layer in the rest of processing channels T may be retained. The remaining part of the support material layer forms a support layer 1019. In this way, on the one hand, the sacrificial layer may be replaced via a processing channel in which the support layer 1019 is not formed, and on the other hand, the device layers L1 and L2 may be supported by the support layer 1019 in the rest of processing channels. After that, the photoresist 1021 may be removed.

An arrangement of the processing channel in which the support layer 1019 is formed and the processing channel in which the support layer 1019 is not formed may be achieved by a pattern of the photoresist 1021. In addition, the processing channel in which the support layer 1019 is formed and the processing channel in which the support layer 1019 is not formed may be substantially evenly distributed for process consistency and uniformity. As shown in FIG. 4, the processing channel in which the support layer 1019 is formed and the processing channel in which the support layer 1019 is not formed may be arranged alternately.

Next, as shown in FIG. 5, the sacrificial layers 1003₁, 1003₂, and 1003₃ may be removed by selective etching via the processing channel T. Due to the existence of the support layer 1019, the device layers L1 and L2 may be kept from collapsing. Gaps left by the removal of the sacrificial layers may be filled with a dielectric material to form isolation layers 1023₁, 1023₂, and 1023₃ by a process of e.g. depositing (for example, atomic layer deposition (ALD) to better control a film thickness) and then etching back (for example, RIE in the vertical direction). A suitable dielectric material, such as oxide, nitride, SiC or a combination of oxide, nitride, or SiC, may be selected for various purposes, such as optimizing reliability of isolation, leakage current or capacitance. Here, in consideration of etching selectivity, the isolation layers 1023₁, 1023₂ and 1023₃ may include oxide (for example, silicon oxide).

Next, the support layer 1019 may be removed by selective etching.

The gate stack may be formed in the processing channel, especially in the processing channel of the device region. Here, a memory function may be achieved by the gate stack for forming the memory device. For example, the gate stack may include a memory structure, such as a charge trapping layer or a ferroelectric material.

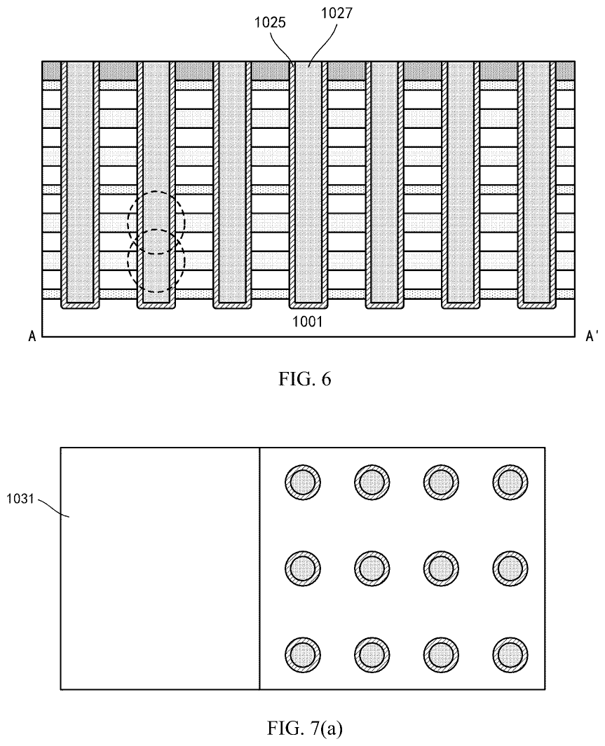

As shown in FIG. 6, a memory functional layer 1025 and a gate conductor layer 1027 may be formed sequentially by, for example, deposition. The memory functional layer 1025 may be formed in a substantially conformal manner. A gap left after the memory functional layer 1025 is formed in the processing channel T may be filled with the gate conductor layer 1027. A planarization treatment, such as chemical mechanical polishing (CMP, for example, CMP may stop at the hard mask layer 1015), may be performed on the formed gate conductor layer 1027 and the formed memory function layer 1025, so that the gate conductor layer 1027 and the memory functional layer 1025 may be left in the processing channel T to form the gate stack.

The memory functional layer 1025 may be based on a dielectric charge trapping, a ferroelectric material effect or a bandgap engineering charge memory (SONOS), etc. For example, the memory functional layer 1025 may include a dielectric tunneling layer (such as an oxide with a thickness of about 1 nm to 5 nm, which may be formed by oxidation or ALD), an energy band offset layer (such as a nitride with a thickness of about 2 nm to 10 nm, which may be formed by CVD or ALD), and an isolation layer (such as an oxide with a thickness of about 2 nm to 6 nm, which may be formed by oxidation, CVD or ALD). Such three-layer structure may lead to an energy band structure that traps electrons or holes. Alternatively, the memory functional layer 1025 may include a ferroelectric material layer, such as HfZrO₂ with a thickness of about 2 nm to 20 nm.

The gate conductor layer 1027 may include, for example, (doped, such as p-doped in the case of the n-type device) polysilicon or a metal gate material.

As shown in FIG. 6, the gate stack (1025/1027) having the memory functional layer is surrounded by the active region. The gate stack is cooperated with the active region (the stack of the source/drain layer, the channel layer, and the source/drain layer) to define the memory cell, as shown in a dotted circle in FIG. 6. The channel region formed in the channel layer may be connected to source/drain regions formed in source/drain layers at opposite ends of the channel region, and the channel region may be controlled by the gate stack.

The gate stack extends in a column shape in the vertical direction and intersects with a plurality of device layers, so as to define a plurality of memory cells stacked on each other in the vertical direction. Memory cells associated with a single gate stack column may form a memory cell string. Corresponding to an arrangement of the gate stack columns (corresponding to the above arrangement of the processing channels T, such as the two-dimensional array), a plurality of such memory cell strings are arranged on the substrate, so as to form a three-dimensional (3D) array of memory cells.

In this embodiment, the single gate stack column may define two memory cells in a single device layer, as shown by two dotted circles in the device layer L1 in FIG. 6. In the NOR-type memory device, such two memory cells may share the same source/drain layer (the second source/drain layer 1009₁ or 1009₂ in the middle), and are electrically connected to the source line. In addition, such two memory cells are electrically connected to bit lines through the source/drain layer on the upper side (the first source/drain layer 1005₁ or 1005₂) and the source/drain layer on the lower side (the third source/drain layer 1013₁ or 1013₂) respectively.

In this way, the fabrication of the memory cell (in the device region) is completed. Then, various electrical contact portions may be fabricated (in the contact region) to achieve a desired electrical connection.

In order to achieve an electrical connection to each device layer, a step structure may be formed in the contact region. Such step structure may be formed in various manners in the art. According to an embodiment of the present disclosure, the step structure may be formed as follows, for example.

As shown in FIG. 6, the current gate stack is exposed at a surface of the hard mask layer 1015. In order to protect the gate stack (in the device region) when fabricating the step structure as following, another hard mask layer 1029 may be formed on the hard mask layer 1015, as shown in FIGS. 7(a), 7(b), and 7(c). For example, the hard mask layer 1029 may include oxide. A photoresist 1031 may be formed on the hard mask layer 1029. The photoresist 1031 is patterned by photolithography to shield the device region and expose the contact region. Selective etching such as RIE may be performed on the hard mask layer 1029, the hard mask layer 1015, the isolation layer 1023₃, and the gate stack by using the photoresist 1031 as an etching mask, so as to expose the device layer. A surface exposed by the photoresist 1031 in the contact region after etching may be substantially planar by controlling an etching depth. For example, the hard mask layer 1029 may be etched and then the gate conductor layer 1027 is etched. The etching of the gate conductor layer 1027 may be stopped near a top surface of the device layer L2. Then the hard mask layer 1015 and the isolation layer 1023₃ may be etched sequentially. After such etching, a top end of the memory functional layer 1025 may protrude above the top surface of the device layer L2 and may be removed by RIE. In this way, a step is formed between the contact region and the device region. Then, the photoresist 1031 may be removed.

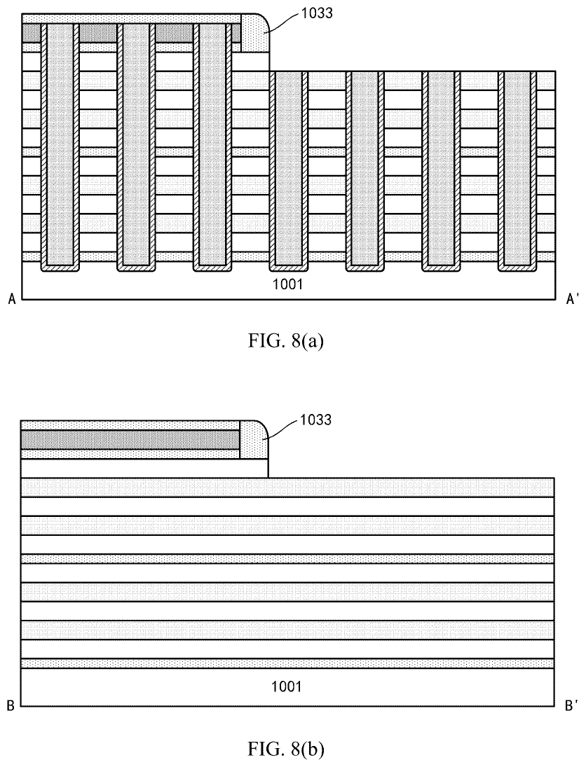

As shown in FIGS. 8(a) and 8(b), a spacer 1033 may be formed at the step between the contact region and the device region through a spacer formation process. For example, a layer of dielectric such as oxide may be deposited in a substantially conformal manner, and then anisotropic etching such as RIE in the vertical direction may be performed on the deposited dielectric, so as to remove a lateral extending portion of the deposited dielectric and retain a vertical extending portion of the deposited dielectric, thereby forming the spacer 1033. Here, considering that the hard mask layer 1029 also includes oxide, an etching depth of the RIE may be controlled to be substantially equal to or slightly greater than a deposition thickness of the dielectric, so as to avoid completely removing the hard mask layer 1029. A width of the spacer 1033 (in the horizontal direction in FIGS. 8(a) and 8(b)) may be basically equal to the deposition thickness of the dielectric. The width of the spacer 1033 defines a size of a landing pad of a contact portion to the third source/drain layer 1013₂ in the device layer L2.

Selective etching such as RIE may be performed on the exposed third source/drain layer 1013₂ and gate stack by using the formed spacer 1033 as an etching mask, so as to expose the second channel layer 1011₂ in the device layer L2. A surface exposed by the spacer 1033 in the contact region after etching may be substantially planar by controlling an etching depth. For example, the third source/drain layer 1013₂ and the gate conductor layer 1027 may be etched. For example, the third source/drain layer 1013₂ and the gate conductor layer 1027 are Si and polycrystalline Si respectively; and if the gate conductor layer 1027 includes a metal gate, the third source/drain layer 1013₂ and the gate conductor layer 1027 may be etched respectively. The etching of the third source/drain layer 1013₂ and the gate conductor layer 1027 may be stopped near a top surface of the second channel layer 1011₂. After such etching, the top end of the memory functional layer 1025 may protrude above the top surface of the second channel layer 1011₂ and may be removed by RIE. In this way, another step is formed between the third source/drain layer 1013₂ and the surface exposed by the spacer 1033 in the contact region.

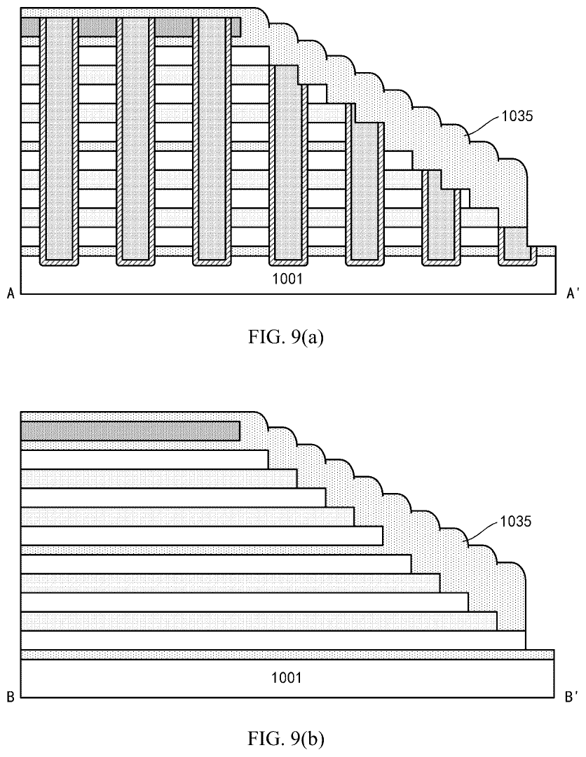

According to the process described above in combination with FIGS. 8(a) and 8(b), the spacer is formed and etching is performed by taking the spacer as the etching mask. Accordingly, a plurality of steps may be formed in the contact region, as shown in FIGS. 9(a) and 9(b). Such steps form such a step structure that in each device layer, each layer to be electrically connected such as the above described source/drain layer and optional channel layer, has an end portion protruded with respect to the upper layer, so as to define a landing pad of a contact portion to the layer. A portion of each formed spacer being left after processing is denoted by 1035 in FIGS. 9(a) and 9(b). Since both the spacer 1035 and the isolation layer are oxide, they are shown here as integral.

Next, the contact portion may be fabricated.

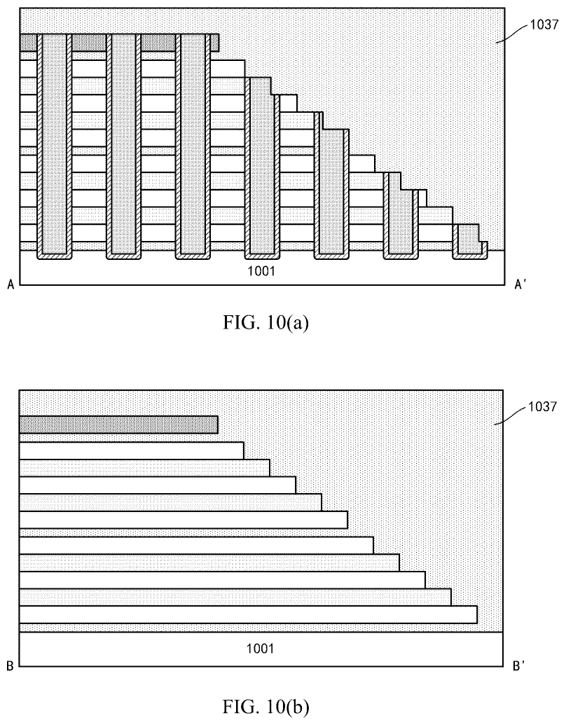

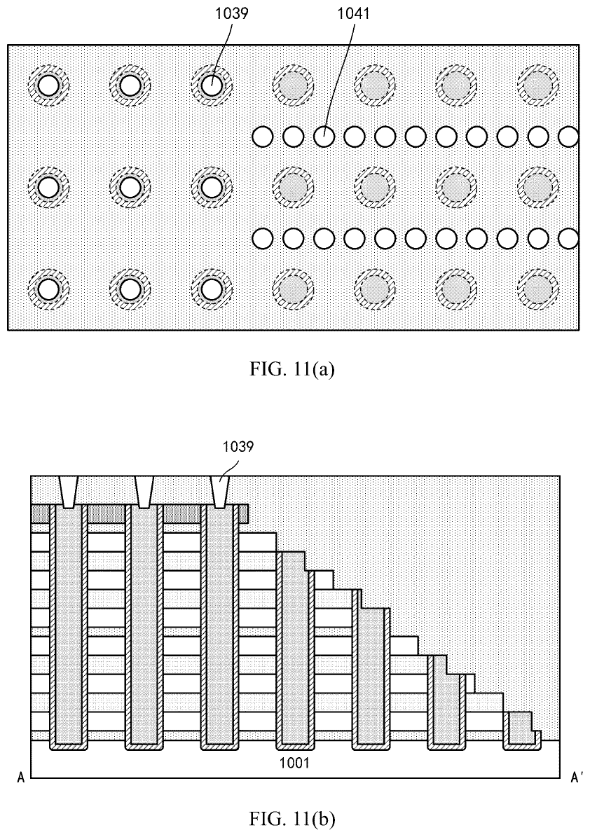

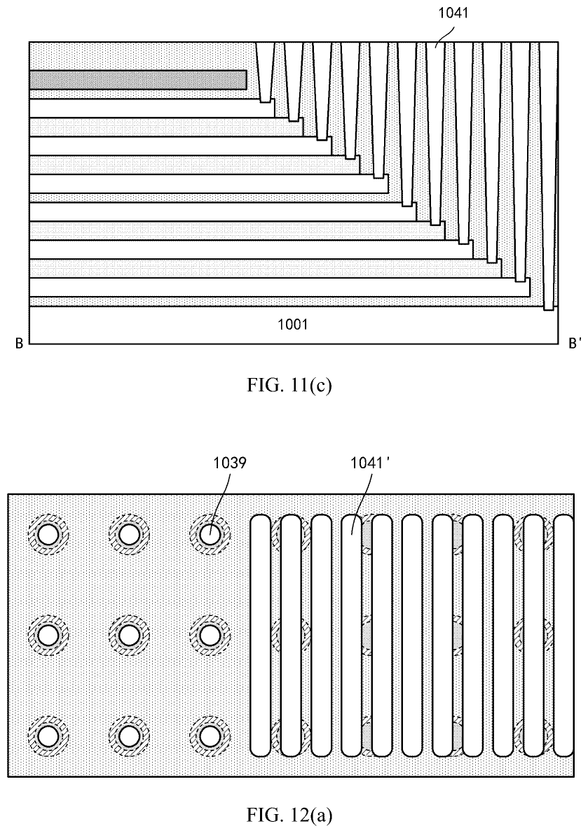

For example, as shown in FIGS. 10(a) and 10(b), an interlayer dielectric layer 1037 may be formed by depositing oxide and planarization such as CMP. Here, since the previously formed spacer 1035 and isolation layer, and the interlayer dielectric layer 1037 are oxides, they are shown as integral. Then, as shown in FIGS. 11(a), 11(b), and 11(c), contact portions 1039 and 1041 may be formed in the interlayer dielectric layer 1037. Specifically, the contact portion 1039 is formed in the device region and electrically connected to the gate conductor layer 1027 in the gate stack. The contact portion 1041 is formed in the contact region and electrically connected to each source/drain layer and channel layer. The contact portion 1041 in the contact region may bypass the gate stack left in the contact region. Such contact portions may be formed by etching the interlayer dielectric layer 1037 to obtain holes and filling the holes with a conductive material such as a metal.

Here, the contact portion 1039 may be electrically connected to a word line. A gate control signal may be applied to the gate conductor layer 1027 through the word line via the contact portion 1039. For two memory cells stacked on each other in the same device layer, the source/drain layer located in the middle, i.e. the second source/drain layer 1009₁ or 1009₂, is shared by these two memory cells and may be electrically connected to the source line via the contact portion 1041. The source/drain layers located at upper and lower ends, i.e. the first source/drain layer 1005₁ or 1005₂ and the third source/drain layer 1013₁ or 1013₂, may be electrically connected to the bit line via the contact portion 1041 respectively. In this way, a NOR-type configuration may be obtained. Here, a contact portion to the channel layer is also formed. Such contact portion may be called a bulk contact portion and may receive a bulk bias, so as to adjust a threshold voltage of the device.

Here, two memory cells are formed in one device layer, which may reduce the number of wirings. However, the present disclosure is not limited thereto. For example, only a single memory cell may be formed in one device layer. In this case, only the first source/drain layer, the first channel layer and the second source/drain layer may be provided in the device layer without the second channel layer and the third source/drain layer.

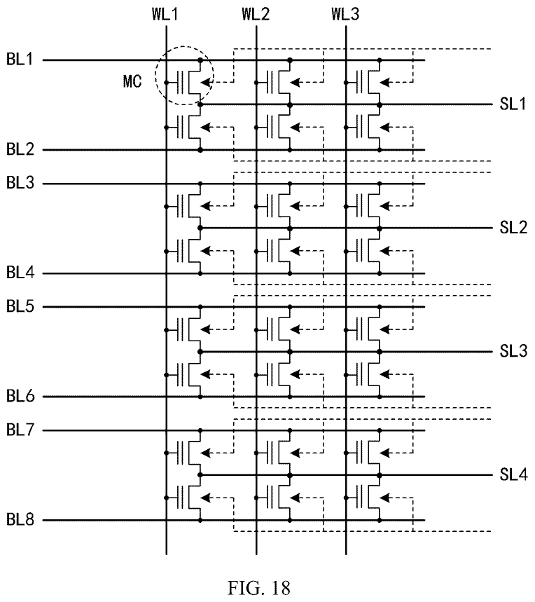

FIG. 18 schematically shows an equivalent circuit diagram of a NOR-type memory device according to an embodiment of the present disclosure.

In an example of FIG. 18, three word lines WL1, WL2, and WL3 and eight bit lines BL1, BL2, BL3, BL4, BL5, BL6, BL7, and BL8 are schematically shown. However, specific numbers of bit lines and word lines are not limited thereto. A memory cell MC is provided at an intersection of the bit line and the word line. FIG. 18 also shows four source lines SL1, SL2, SL3, and SL4. As described above, the adjacent memory cells of every two layers in the vertical direction may share the same source line connection. In addition, respective source lines may be connected to each other, so that respective memory cells MC may be connected to a common source line. In addition, an optional bulk connection to each memory cell is schematically shown in FIG. 18 with dotted lines. As described below, the bulk connection of each memory cell may be electrically connected to a source line of the memory cell.

Here, a two-dimensional array of memory cells MC is shown for illustration convenience only. A plurality of such two-dimensional arrays may be arranged in a direction (for example, a direction perpendicular to the paper surface in FIG. 18) of intersection with this two-dimensional array, so as to obtain a three-dimensional array.

In FIG. 18, an extension direction of the word lines WL1 to WL3 may correspond to an extension direction of the gate stack, that is, the vertical direction with respect to the substrate in the above embodiment. In this direction, adjacent bit lines are isolated from each other. For this purpose, the isolation layer is arranged between adjacent device layers in the vertical direction in the above embodiment.

In the above embodiment, the contact portion 1041 in the contact region is desired to bypass the gate stack left in the contact region. According to another embodiment of the present disclosure, an isolation such as the dielectric material may be formed at a top end of the gate stack left in the contact region, so that it is not necessary to deliberately by pass the residual gate stack.

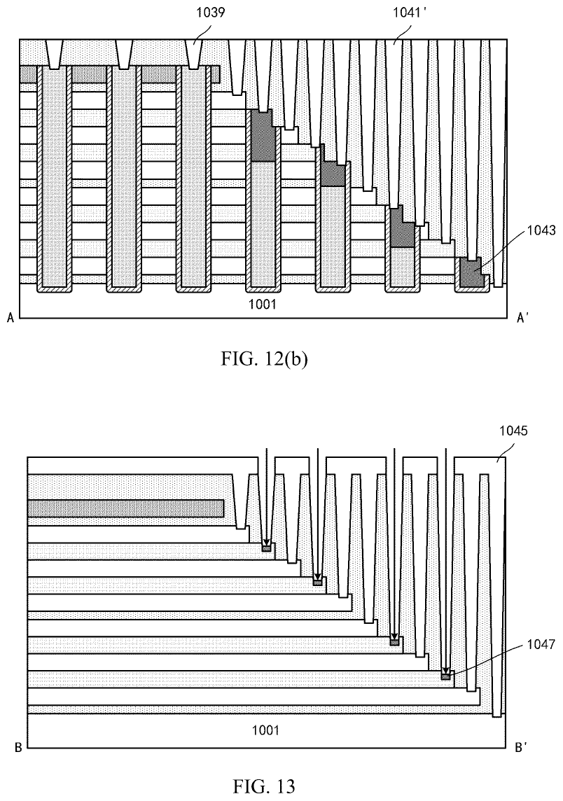

For example, as shown in FIGS. 12(a) and 12(b), after the step structure is formed in the contact region as described above in combination with FIGS. 7(a) to 9(b), the isolation layer and the spacer 1035 may be removed by selective etching, such as RIE, so as to expose a top end of each gate stack (in the device region and the contact region). The gate stack in the device region may be shielded by a shielding layer, such as a photoresist, so as to expose the gate stack in the contact region. For the gate stack exposed in the contact region, the gate conductor layer may be recessed by a factor of, for example, about 50 nm to 150 nm, through selective etching such as RIE. After that, the shielding layer may be removed. A gap formed due to the recess of the gate conductor layer in the contact region may be filled with the dielectric material such as SiC by, for example, depositing and then etching back, so as to form an isolation plug 1043.

Next, the interlayer dielectric layer may be formed according to the above embodiment, and contact portions 1039 and 1041′ may be formed in the interlayer dielectric layer. In this example, the contact portion 1041′ in the contact region may extends into the isolation plug 1043. Therefore, the contact portion 1041′ may not be limited to be in form of plug described above, but may be formed as a strip, so as to reduce a contact resistance. The strip contact portion 1041′ may extend along a landing pad (i.e., the step in the step structure) of a corresponding layer.

In the above embodiment, since the channel layer is lightly doped or not intentionally doped, a contact resistance between the bulk contact portion and the channel layer may be relatively large. According to another embodiment of the present disclosure, a relatively highly doped region may be formed at a position where the channel layer is in contact with the bulk contact portion, so as to reduce the contact resistance. For example, after the interlayer dielectric layer is formed and the holes for the contact portions are formed in the interlayer dielectric layer by etching as described above, a photoresist 1045 may be formed. The photoresist 1045 is patterned by photolithography to expose holes for bulk contact portions to be formed. A highly doped region 1047 may be formed in a landing pad of the channel layer via these holes by, for example, ion implantation. A doping type of the highly doped region 1047 may be the same as that of the channel layer, but a doping concentration of the highly doped region 1047 is higher than that of at least a part of the rest of the channel layer. Then, the photoresist 1045 may be removed. After that, the contact portions may be formed in the holes of the interlayer dielectric layer.

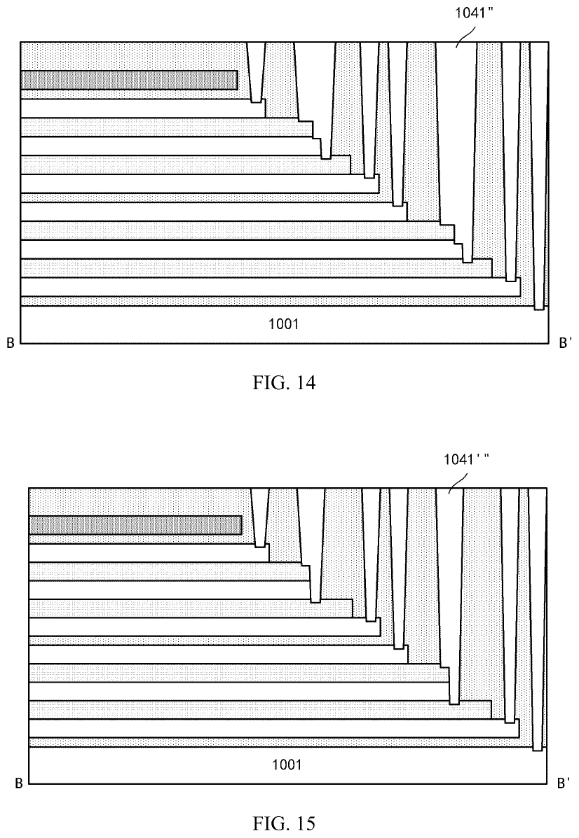

In the above embodiment, the bulk contact portion is provided separately. According to another embodiment of the present disclosure, the bulk contact portion may be integrated with a source line contact portion, so as to save area. For example, as shown in FIGS. 14 and 15, contact portions 1041″ and 1041′″ may be in contact with the second source/drain layer, and the first channel layer and the second channel layer above and below the second source/drain layer in each device layer. The difference between embodiments in FIGS. 14 and 15 is that a step structure in a contact region of FIG. 14 is different from a step structure in a contact region of FIG. 15. In the embodiment shown in FIG. 14, steps may be formed between the second source/drain layer and the first channel layer and between the second source/drain layer and the second channel layer. However, in the embodiment shown in FIG. 15, step may not be formed between the second source/drain layer and the second channel layer, so as to further save area.

In the above embodiment, the contact portion is in direct contact with the corresponding landing pad. According to another embodiment of the present disclosure, silicide may be formed at the landing pad, so as to reduce the contact resistance. More specifically, at each step of the contact region, a transverse surface of the step is used as a landing pad on which silicide may be formed. On the other hand, silicide may not be formed on a vertical surface of the step, so as to avoid a short circuit between landing pads of adjacent steps.

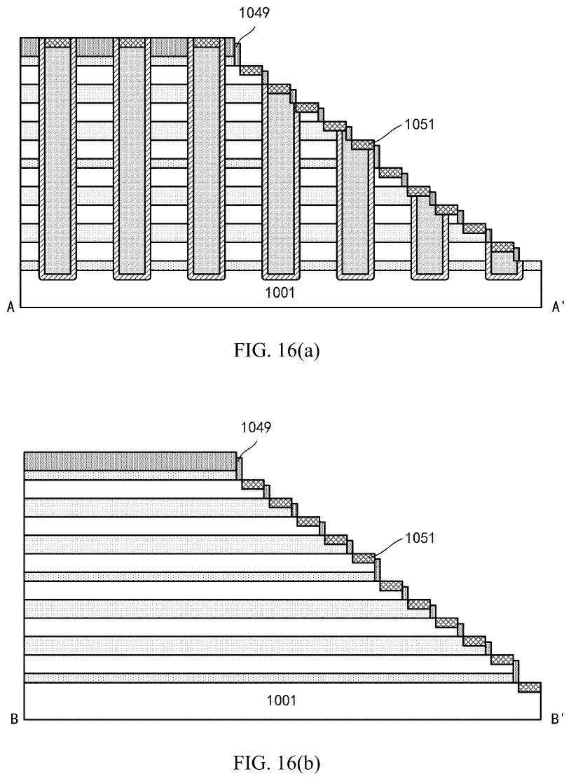

For example, as shown in FIGS. 16(a) and 16(b), after the step structure is formed in the contact region as described above in combination with FIGS. 7(a) to 9(b), the isolation layer and the spacer 1035 may be removed by selective etching such as RIE, so as to expose a surface of each step in the contact region. A dielectric spacer 1049, such as nitride, may be formed on the vertical surface of each step by the spacer formation process, so as to shield the vertical surface of each step to avoid a subsequent silicification reaction. Then, an exposed transverse surface of each step may be silicified. For example, a metal such as NiPt may be deposited and annealed, so that silicification reaction is conducted between the deposited metal and a semiconductor material (such as Si) at the transverse surface of each step, so as to generate a conductive metal silicide 1051 such as NiPtSi. An unreacted metal may then be removed.

In the example as shown, the gate conductor layer 1027 is polysilicon for example. Accordingly, a top end of the gate conductor layer 1027 may also undergo the silicification reaction and thus be covered by silicide. When the gate conductor layer 1027 is the metal gate, a protective layer (for example, nitride) may be formed on the device region to cover the gate stack and then be silicified. Accordingly, the gate conductor layer 1027 may be prevented from being damaged by etching when removing the metal in the silicification process.

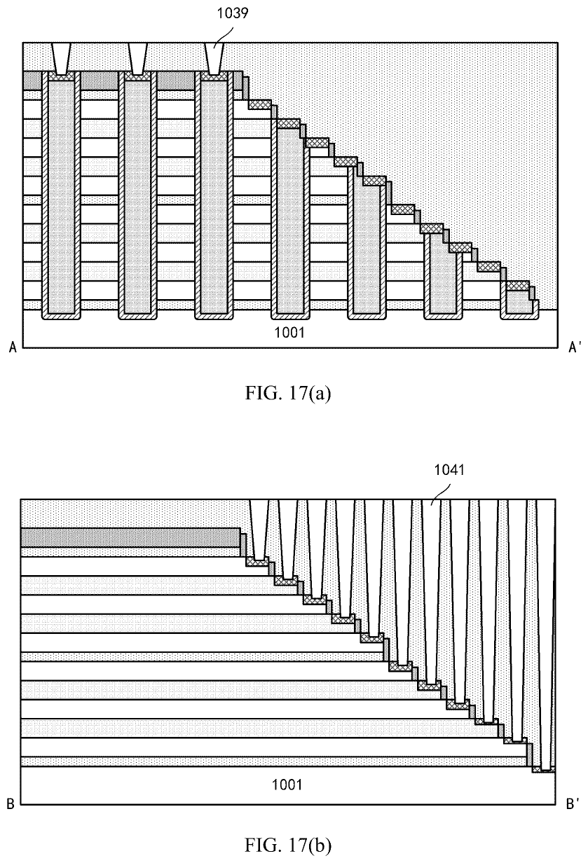

Next, as shown in FIGS. 17(a) and 17(b), the interlayer dielectric layer may be formed as described above, and the contact portions 1039 and 1041 may be formed in the interlayer dielectric layer. When etching the holes used for the contact portions, the silicide 1051 may be used as an etching stop layer. Therefore, an etching depth of the hole may be better controlled.

The memory device according to the embodiments of the present disclosure may be applied to various electronic apparatuses. For example, the memory device may store various programs, applications and data required for an operation of the electronic apparatus. The electronic apparatus may further include a processor cooperated with the memory device. For example, the processor may operate the electronic apparatus by running a program stored in the memory device. Such electronic apparatus includes, for example, a smart phone, a personal computer (PC), a tablet, an artificial intelligence device, a wearable device, or a mobile power supply, etc.

In the above description, the technical details such as patterning and etching of each layer are not described in detail. However, those skilled in the art should understand that various technical means may be employed to form a layer, a region or the like having a desired shape. In addition, in order to form the same structure, those skilled in the art may also design a method that is not completely the same as the method described above. In addition, although the respective embodiments are described above separately, this does not mean that the measures in the respective embodiments cannot be advantageously used in combination.

The embodiments of the present disclosure have been described above. However, these examples are for illustrative purposes only, and are not intended to limit the scope of the present disclosure. The scope of the present disclosure is defined by the appended claims and their equivalents. Without departing from the scope of the present disclosure, those skilled in the art may make various substitutions and modifications, and these substitutions and modifications should fall within the scope of the present disclosure.

1. A NOR-type memory device, comprising:
a plurality of device layers disposed on a substrate, wherein each of the plurality of device layers comprises a stack of a first source/drain layer, a first channel layer, and a second source/drain layer; and
a gate stack that extends vertically with respect to the substrate to pass through the stack in the each of the plurality of device layers, wherein the gate stack comprises a gate conductor layer and a memory functional layer disposed between the gate conductor layer and the stack, and a memory cell is defined at an intersection of the gate stack and the stack.

2. The NOR-type memory device according to claim 1, wherein the stack of at least one of the plurality of device layers further comprises a second channel layer and a third source/drain layer, and two memory cells stacked with each other are defined at the intersection of the gate stack and the stack.

3. The NOR-type memory device according to claim 1, wherein the memory functional layer comprises at least one of a charge trapping material or a ferroelectric material.

4. The NOR-type memory device according to claim 1, wherein the stack comprises a single crystal semiconductor material.

5. The NOR-type memory device according to claim 1, wherein an isolation layer is disposed between at least one pair of adjacent device layers among the plurality of device layers.

6. The NOR-type memory device according to claim 5, wherein a bit line that is electrically connected to a source/drain layer adjacent to the isolation layer in a device layer above the isolation layer is different from a bit line that is electrically connected to a source/drain layer adjacent to the isolation layer in a device layer below the isolation layer.

7. The NOR-type memory device according to claim 1, wherein the memory functional layer is formed on a bottom surface of the gate conductor layer and a sidewall of the gate conductor layer.

8. The NOR-type memory device according to claim 1, wherein the NOR-type memory device comprises a plurality of gate stacks disposed in an array.

9. The NOR-type memory device according to claim 2, wherein the first source/drain layer, the first channel layer, the second source/drain layer, the second channel layer, and the third source/drain layer comprise the same semiconductor material, wherein a doping concentration interface is provided between adjacent layers.

10. The NOR-type memory device according to claim 2, further comprising:
a first bit line and a second bit line that is different from the first bit line;
a source line;
a first contact portion to the first source/drain layer;
a second contact portion to the second source/drain layer; and
a third contact portion to the third source/drain layer,
wherein the first contact portion and the third contact portion are electrically connected to the first bit line and the second bit line respectively, and the second contact portion is electrically connected to the source line.

11. The NOR-type memory device according to claim 10, further comprising:
a fourth contact portion to the first channel layer; and
a fifth contact portion to the second channel layer.

12. The NOR-type memory device according to claim 11, wherein the first contact portion, the second contact portion, the third contact portion, the fourth contact portion and the fifth contact portion are formed as strips extending substantially parallel to each other.

13. The NOR-type memory device according to claim 11, further comprising:
a first highly doped region that is located in the first channel layer in contact with the fourth contact portion and has a doping concentration higher than a doping concentration of at least a part of the rest of the first channel layer; and
a second highly doped region that is located in the second channel layer in contact with the fifth contact portion and has a doping concentration higher than a doping concentration of at least a part of the rest of the second channel layer.

14. The NOR-type memory device according to claim 10, wherein the second contact portion is further electrically connected to the first channel layer and the second channel layer.

15. The NOR-type memory device according to claim 14, wherein:
an end portion of the second source/drain layer is substantially aligned with an end portion of the second channel layer, and an end portion of the first channel layer is relatively protruded; or
an end portion of the first channel layer protrudes with respect to an end portion of the second source/drain layer, and the end portion of the second source/drain layer protrudes with respect to an end portion of the second channel layer.

16. The NOR-type memory device according to claim 10, wherein the substrate comprises a device region and a contact region adjacent to the device region, the memory cell is formed on the device region, and the contact portions are formed on the contact region.

17. The NOR-type memory device according to claim 16, wherein the first source/drain layer, the first channel layer, the second source/drain layer, the second channel layer, and the third source/drain layer in each of the plurality of device layers form a step structure in the contact region.

18. The NOR-type memory device according to claim 17, wherein the step structure comprises a step with a transverse surface and a vertical surface, and the NOR-type memory device further comprises:
a silicide on the transverse surface of the step; and
a dielectric spacer on the vertical surface of the step.

19. The NOR-type memory device according to claim 1, further comprising:
a word line; and
a sixth contact portion to the gate conductor layer, wherein the sixth contact portion is electrically connected to the word line.

20. A method of manufacturing a NOR-type memory device, comprising:
disposing a plurality of device layers on a substrate, wherein each of the plurality of device layers comprises a stack of a first source/drain layer, a first channel layer, and a second source/drain layer;
forming a processing channel that extends vertically with respect to the substrate to pass through the stack in the each of the plurality of device layers; and
forming a gate stack in the processing channel, wherein the gate stack comprises a gate conductor layer and a memory functional layer disposed between the gate conductor layer and the stack, and a memory cell is defined at an intersection of the gate stack and the stack.

21. The method according to claim 20, wherein the stack of at least one of the plurality of device layers further comprises a second channel layer and a third source/drain layer.

22. The method according to claim 20, wherein the stack is formed by epitaxial growth.

23. The method according to claim 22, wherein each layer in the stack is doped in situ during epitaxial growth.

24. The method according to claim 20, further comprising:
forming a sacrificial layer between at least one pair of adjacent device layers,
wherein after disposing the plurality of device layers, the method further comprises replacing the sacrificial layer with an isolation layer.

25. The method according to claim 24, wherein replacing the sacrificial layer with the isolation layer comprises:
forming a support layer in one or more of processing channels, so that the sacrificial layer is exposed in the rest of the processing channels;
replacing the sacrificial layer with the isolation layer via the rest of the processing channels; and
removing the support layer.

26. The method according to claim 20, wherein forming the gate stack comprises:
forming the memory functional layer on a bottom surface of the processing channel and a sidewall of the processing channel in a substantially conformal manner; and
filling the processing channel, on which the memory functional layer is formed, with the gate conductor layer.

27. The method according to claim 20, wherein a plurality of processing channels disposed in an array is formed.

28. The method according to claim 21, wherein the substrate comprises a device region and a contact region adjacent to the device region, the memory cell is formed on the device region, and
the method further comprises:
forming, on the contact region, a first contact portion to the first source/drain layer, a second contact portion to the second source/drain layer, and a third contact portion to the third source/drain layer.

29. The method according to claim 28, further comprising:
forming, on the contact region, a fourth contact portion to the first channel layer and a fifth contact portion to the second channel layer.

30. The method according to claim 29, wherein the first contact portion, the second contact portion, the third contact portion, the fourth contact portion and the fifth contact portion are formed as strips extending substantially parallel to each other.

31. The method according to claim 29, further comprising:
forming, at a place where the first channel layer is in contact with the fourth contact portion, a first highly doped region having a doping concentration higher than a doping concentration of at least a part of the rest of the first channel layer; and
forming, at a place where the second channel layer is in contact with the fifth contact portion, a second highly doped region having a doping concentration higher than a doping concentration of at least a part of the rest of the second channel layer.

32. The method according to claim 28, wherein the second contact portion is further formed to be electrically connected to the first channel layer and the second channel layer.

33. The method according to claim 28, further comprising:
patterning the first source/drain layer, the first channel layer, the second source/drain layer, the second channel layer, and the third source/drain layer in the each of the plurality of device layers into a step structure in the contact region.

34. The method according to claim 33, wherein the step structure comprises a step with a transverse surface and a vertical surface, and the method further comprises:
forming a dielectric spacer on the vertical surface of the step; and
siliconizing the transverse surface of the step.

35. An electronic apparatus comprising the NOR-type memory device according to claim 1.

36. The electronic apparatus according to claim 35, wherein the electronic apparatus comprises a smart phone, a computer, a tablet, an artificial intelligence device, a wearable device, or a mobile power supply.
